(19) United States
(12) Patent Application Publication
(10) Pub. No.: US 2024/0206301 A1
(43) Pub. Date: Jun. 20, 2024

(54) DISPLAY DEVICE

(71) Applicant: LG Display Co., Ltd., Seoul (KR)

(72) Inventors: KyungKook JANG, Gyeonggi-do (KR); SeongHan HWANG, Gyeonggi-do (KR); DaBin KIM, Gyeonggi-do (KR); ByungGwan HYUN, Gyeonggi-do (KR)

(73) Assignee: LG Display Co., Ltd., Seoul (KR)

(21) Appl. No.: 18/527,436

(22) Filed: Dec. 4, 2023

(30) Foreign Application Priority Data
Dec. 19, 2022 (KR) 10-2022-0178212

(51) Int. Cl. H10K 59/80; H10K 59/122; H10K 59/60

(52) U.S. Cl. CPC H10K 59/8792; H10K 59/122; H10K 59/60; H10K 59/351

(57) ABSTRACT

Aspects of the present disclosure relate to a display device and, more particularly, may provide a display device capable of implementing black characteristics by absorbing a whole wavelength band of visible light and improving a black visual sense by including a substrate including a light emission region and a non-light emission region, a light-emitting element disposed on the substrate and including a first electrode, a light-emitting layer, and a second electrode, and a bank layer defining an opening part of the light emission region and containing a nano rod.

### CROSS-REFERENCE TO RELATED APPLICATION

This application claims the priority of Korean Patent Application No. 10-2022-0178212, filed on Dec. 19, 2022, which is hereby incorporated by reference in its entirety.

### BACKGROUND

### Field of the Disclosure

The present disclosure relates to a display device and more particularly, for example, without limitation, to a display device including a bank layer defining an opening part of the light emission region and containing a nano rod.

### Description of the Background

In accordance with development into an information society, requests for display devices for displaying images have increased in various forms, and, recently, various flat panel display devices such as a liquid crystal display device (LCD), a plasma display panel device (PDP), and an organic light-emitting diode display device (OLED) are used.

Among such display devices, the organic light-emitting diode display device does not require a back light used in a liquid crystal display device using a non-light-emitting element by using a self-light-emitting element and thus may realize a light weight and a thin type. In addition, the organic light-emitting diode display device has a superior viewing angle and a superior contrast ratio over a liquid crystal display device and is advantageous in terms of power consumption.

However, in a case in which a transparent bank layer is applied as a pixel definition film of a display device, there is a problem in that reflectivity of a panel according to reflection in an electrode part increases.

The description provided in the description of the background section should not be assumed to be prior art merely because it is mentioned in or associated with the description of the background section. The description of the background section may include information that describes one or more aspects of the subject technology, and the description in this section does not limit the disclosure.

### SUMMARY

Accordingly, the present disclosure is directed to a display device that substantially obviates one or more of problems due to limitations and disadvantages described above.

More specifically, the present disclosure is to provide a display device that is capable of implementing black characteristics by absorbing the whole wavelength band of visible light and improving a black visual sense by introducing nano rods into a bank layer.

The present disclosure is also to provide a display device that is capable of implementing black characteristics by absorbing the whole wavelength band of visible light and improving a black visual sense by introducing nano rods into a bank layer.

The present disclosure is also to provide a display device capable of implementing black characteristics by absorbing a whole wavelength band of visible light and improving a black visual sense by including a substrate including a light emission region and a non-light emission region, a light-emitting element disposed on the substrate and including a first electrode, a light-emitting layer, and a second electrode, and a bank layer defining an opening part of the light emission region and containing a nano rod.

The present disclosure is also to provide a display device that is capable of implementing near-infrared light emission characteristics by absorbing a light source of a visible light region emitted from a light-emitting element by introducing nano rods into a bank layer.

The present disclosure is also to provide a display device that is capable of improving the process and dispersion stability of materials by lowering a solid content by introducing nano rods into a bank layer.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a substrate including a light emission region and a non-light emission region; a light-emitting element disposed on the substrate and including a first electrode, a light-emitting layer, and a second electrode; and a bank layer defining an opening part of the light emission region and containing a nano rod.

In another aspect of the present disclosure, a display device includes a substrate including at least one subpixel; a bank layer disposed on the substrate and defining the subpixel; and a light receiving part disposed adjacent to the bank layer and receiving light of a near-infrared region, in which the bank layer contains a nano rod absorbing light of a visible light region and emitting light of the near-infrared region.

Other details of the exemplary aspects are included in the detailed description and the drawings.

According to various aspects of the present disclosure, a display device that is capable of implementing black characteristics by absorbing the whole wavelength band of visible light and improving a black visual sense by introducing nano rods into a bank layer may be provided.

According to various aspects of the present disclosure, by introducing nano rods into a bank layer, a display device that is capable of implementing near-infrared light emission characteristics by absorbing a light source of a visible light region emitted from a light-emitting element may be provided.

According to various aspects of the present disclosure, by introducing nano rods into a bank layer, a display device that may improve the process and dispersion stability of materials by lowering a solid content may be provided.

According to various aspects of the present disclosure, by introducing nano rods into a bank layer, a display device that enables process optimization may be provided.

It is to be understood that in addition to the effects of the present disclosure as mentioned above, additional advantages and features of the present disclosure will be clearly understood by those skilled in the art from the above description of the present disclosure.

### BRIEF DESCRIPTION OF THE DRAWINGS

The above and other features and advantages of the present disclosure will be more clearly understood from the following detailed description taken in conjunction with the accompanying drawings, in which:

FIG. 1 is a system configuration diagram of a display device according to aspects of the present disclosure.

FIG. 2 is an equivalent circuit of a subpixel of a display device according to aspects of the present disclosure.

FIG. 3 is another equivalent circuit of a subpixel of a display device according to aspects of the present disclosure.

FIG. 4 is a diagram illustrating a light shield inside a subpixel of a display device according to aspects of the present disclosure.

FIG. 5 is a plan view illustrating an example of subpixels disposed in an X area illustrated in FIG. 1.

FIG. 6 is a cross-sectional view illustrating a cross-section of a subpixel cut along line I-I′ illustrated in FIG. 5.

FIG. 7 is a diagram illustrating a process in which, when a touch on a surface of a display device using a finger, a near-infrared ray is received by a light receiving part, and the touch is detected in the structure illustrated in FIG. 6.

FIG. 8A is a schematic diagram illustrating a shape of a nano rod, and FIG. 8B is a photograph illustrating nano rods included in a bank layer.

FIG. 9A is a schematic diagram showing another shape of a nano rod, and FIG. 9B is a photograph illustrating nano rods of another shape included in a bank layer.

FIGS. 10 to 12 are graphs illustrating optical characteristics of a display device according to aspects of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or aspects of the present disclosure, reference will be made to the accompanying drawings in which it is shown by way of illustration specific examples or aspects that may be implemented, and in which the same reference numerals and signs may be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “include,” “have,” “comprise,” “contain,” “constitute” “make up of,” d “formed of” and “consist of” used herein are generally intended to allow other components to be added unless the terms are used with such as the term “only.” As used herein, singular forms are intended to include plural forms unless the context clearly indicates otherwise. Terms, such as “first,” “second,” “A,” “B,” “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps” etc. a second element, it should be interpreted that, not only may the first element “be directly connected or coupled to” or “directly contact or overlap” the second element, but a third clement may also be “interposed” between the first and second elements, or the first and second elements may “be connected or coupled to”, “contact or overlap”, etc. each other via a fourth element. Here, the second element may be included in at least one of two or more elements that “are connected or coupled to”, “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

When the position relation between two parts is described using the terms such as “on,” “above,” “over,” “below,” “under,” “beside,” “beneath,” “near”, “close to,” “adjacent to”, “on a side of”, “next” or the like, one or more parts may be positioned between the two parts unless the terms are used with the term such as “immediately” or “directly”.

Spatially relative terms, such as “under, ” “below, ” “beneath,” “lower, ” “over,” “upper” and the like, may be used herein for ease of description to describe one element or feature's relationship to another element (s) or feature (s) as illustrated in the figures. It will be understood that the spatially relative terms may encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” may encompass both an orientation of below and above. Similarly, the exemplary term “above” or “over” may encompass both an orientation of “above” and “below.” In addition, when any dimensions, relative sizes, etc. are mentioned, it should be considered that numerical values for an elements or features, or corresponding information (e. g., level, range, etc.) include a tolerance or error range that may be caused by various factors (e. g., process factors, internal or external impact, noise, etc.) even when a relevant description is not specified. Further, the term “may” fully encompasses all the meanings of the term “may.”

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

A term “device” used herein may refer to a display device including a display panel and a driver for driving the display panel. Examples of the display device may include a light emitting diode (LED), and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including LED and the like, but aspects of the present disclosure are not limited thereto.

A size and a thickness of each component illustrated in the drawing are illustrated for convenience of description, and the present disclosure is not limited to the size and the thickness of the component illustrated.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example aspects belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

When reference numerals are given to elements of drawings describing the aspects of the present disclosure, the same elements are designated by the same reference numerals as much as possible even though they are shown in different drawings.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, various aspects of the present disclosure will be described in detail with reference to the attached drawings.

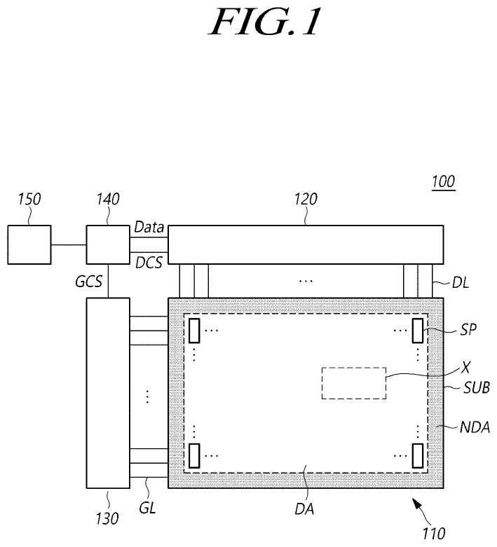

FIG. 1 is a system configuration diagram of a display device (100) according to aspects of the present disclosure. All the components of each display device according to all aspects of the present disclosure are operatively coupled and configured.

Referring to FIG. 1, the display device (100) according to aspects of the present disclosure may include a display panel (110) and a drive circuit used for driving the display panel (110).

The drive circuit may include a data driving circuit (120), a gate driving circuit (130), and the like and may further include a controller (140) that controls the data driving circuit (120) and the gate driving circuit (130).

The display panel (110) may include a substrate (SUB) and signal wirings such as multiple data lines (DL) and multiple gate lines (GL) disposed on the substrate (SUB). The display panel (110) may include multiple subpixels (SP) connected to multiple data lines (DL) and multiple gate lines (GL). For example, multiple data lines (DL) and multiple gate lines (GL) are cross each other to define the multiple subpixels (SP).

The display panel (110) may include a display region (DA) in which a video is displayed and a non-display region (NDA) in which no video is displayed. The non-display region (NDA) is disposed in the vicinity of (e.g., adjacent to) the display region (DA) or to surround the display region (DA). In the display panel (110), multiple subpixels (SP) used for displaying an image may be disposed in the display region (DA), drive circuits (120, 130, 140) may be electrically connected to or the drive circuits (120, 130, 140) may be mounted in the non-display region (NDA), and a pad part to which an integrated circuit, a printed circuit, or the like is connected may be disposed.

The data driving circuit (120) is a circuit used for driving multiple data lines (DL) and may supply data signals to the multiple data lines (DL). The gate driving circuit (130) is a circuit used for driving multiple gate lines (GL) and may supply gate signals to the multiple gate lines (GL). The controller (140) may supply a data control signal (DCS) to the data driving circuit (120) for controlling an operation timing of the data driving circuit (120). The controller (140) may supply a gate control signal (GCS) used for controlling an operation timing of the gate driving circuit (130) to the gate driving circuit (130). For example, the data driving circuit 120 may receive data signal from the controller 140 and convert the data signal into an analog data voltage Vdata and the gate driving circuit 130 may generate a gate signal of a turn-on level voltage or a gate signal of a turn-off level voltage according to the gate control signal GCS.

The controller (140) may start scanning in accordance with a timing implemented in each frame, convert input video data input from the outside to match a data signal format used by the data driving circuit (120), supply converted video data (Data) to the data driving circuit (120), and control data driving at an appropriate time according to scanning.

To control the gate driving circuit (130), the controller (140) may output various gate control signals (GCS) including a gate start pulse (GSP), a gate shift clock (GSC), a gate output enable signal (GOE), and the like.

To control the data driving circuit (120), the controller (140) may output various data control signals (DCS) including a source start pulse (SSP), a source sampling clock (SSC), a source output enable signal (SOE), and the like.

The controller (140) may be implemented using a component separated from the data driving circuit (120) or may be integrated with the data driving circuit (120) and implemented using an integrated circuit.

The data driving circuit (120) receives video data (Data) as input from the controller (140) and supplies a data voltage to multiple data lines (DL), thereby driving the multiple data lines (DL). Here, the data driving circuit (120) is also called a source driving circuit. For example, each source driving circuit may include a shift register, a latch circuit, a digital-to-analog converter, an output buffer, and the like.

Such a data driving circuit (120) may include one or more source driver integrated circuits (SDIC).

For example, each source driver integrated circuit (SDIC) may be connected to the display panel (110) using a tape automated bonding (TAB) method, may be connected to a bonding pad of the display panel (110) using a Chip On Glass (COG) or Chip On Panel (COP) method, or may be implemented using a Chip On Film (COF) method and connected to the display panel (110).

The gate driving circuit (130) may include one or more gate driver integrated circuits. The gate driving circuit (130) may output either a gate signal of a turn-on level voltage or a gate signal of a turn-off level voltage in accordance with control of the controller (140). The gate driving circuit (130) may sequentially drive multiple gate lines (GL) by sequentially supplying gate signals of the turn-on level voltage to the multiple gate lines (GL).

The gate driving circuit (130) may be connected to the display panel (110) using a Tape Automated Bonding (TAB) method, may be connected to a bonding pad of the display panel (110) using a Chip-On-Glass (COG) or Chip-On-Panel (COP) method, or may be connected to the display panel (110) using a chip one film (COF) method. Alternatively, the gate driving circuit (130) may be formed in a non-display region (NDA) of the display panel (110) as a Gate In Panel (GIP) type. The gate driving circuit (130) may be disposed on the substrate (SUB) or may be connected to the substrate (SUB). In other words, in the case of the GIP type, the gate driving circuit (130) may be disposed in the non-display region (NDA) of the substrate (SUB). In the case of the Chip-On-Glass (COG) type, the Chip-On-Film (COF) type, or the like, the gate driving circuit (130) may be connected to the substrate (SUB).

The substrate (SUB) may include glass, plastic, or a flexible polymer film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC) film, polyvinyl alcohol(PVA) film, and polystyrene(PS), and the present disclosure is not limited thereto.

On the other hand, at least one of the data driving circuit (120) and the gate driving circuit (130) may be disposed in the display region (DA). For example, at least one of the data driving circuit (120) and the gate driving circuit (130) may be disposed not to overlap with subpixels (SP) or may be disposed to overlap with the subpixels (SP) in a part or whole.

When a specific gate line (GL) is driven by the gate driving circuit (130), the data driving circuit (120) may convert video data (Data) received from the controller (140) into a data voltage of an analog form and supply the data voltage to multiple data lines (DL). The multiple data lines (DL) may be connected with the data driving circuit (120) through data pads.

The data driving circuit (120) may be connected to one side (for example, an upper side or a lower side) of the display panel (110). In accordance with a drive system, a panel design system, and the like, the data driving circuit (120) may be connected to both sides (for example, an upper side and a lower side) of the display panel (110) or may be connected to two or more side faces out of four side faces of the display panel (110).

The gate driving circuit (130) may be connected to one side (for example, a left side or a right side) of the display panel (110). In accordance with a drive system, a panel design system, and the like, the gate driving circuit (130) is connected to both sides (for example, a left side and a right side) of the display panel (110) or may be connected to two or more side faces among four side faces of the display panel (110). However, the aspect of present disclosure is not limited thereto, the position of gate driving circuit (130) and data driving circuit (120) may be exchanged.

The controller (140) is a timing controller used in a general display technology, may be a control device that includes a timing controller and may additionally perform another control function, may be a control device other than a timing controller, or may be a circuit disposed inside a control device. The controller (140) may be implemented using various circuits and electronic components such as an Integrated Circuit (IC), a Field Programmable Gate Array (FPGA), an Application Specific Integrated Circuit (ASIC), a processor, and the like.

The controller (140) is mounted in a printed circuit board, a flexible printed circuit, or the like and may be electrically connected to the data driving circuit (120) and the gate driving circuit (130) through the printed circuit board, the flexible printed circuit, or the like.

The display device (100) according to aspects of present disclosure may be either a display including a back light unit such as a liquid crystal display device or the like or a self-emission display such as an Organic Light-emitting Diode (OLED) display, a quantum dot display, a micro light-emitting diode (LED) display, or the like.

In a case in which the display device (100) according to the aspects of the present disclosure is the OLED display, each subpixel may include an organic light-emitting diode (OLED) emitting light for itself as a light-emitting element. In a case in which a display device (100) according to the aspects of the present disclosure is a quantum dot display, each subpixel (SP) may include a light-emitting element formed using a quantum dot that is a semiconductor crystal emitting light for itself. In a case in which a display device (100) according to the aspects of the present disclosure is an LED display, each subpixel (SP) may include a micro light-emitting diode (LED) that emits light for itself and is formed on the basis of an inorganic material as a light-emitting element.

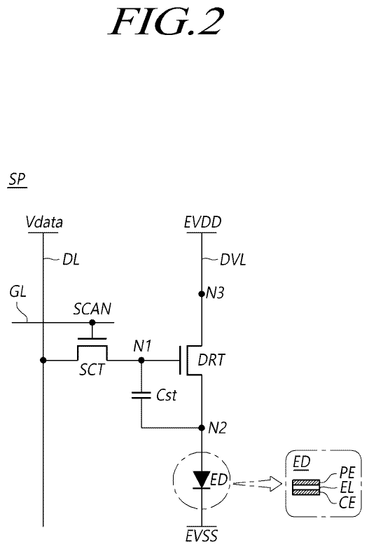

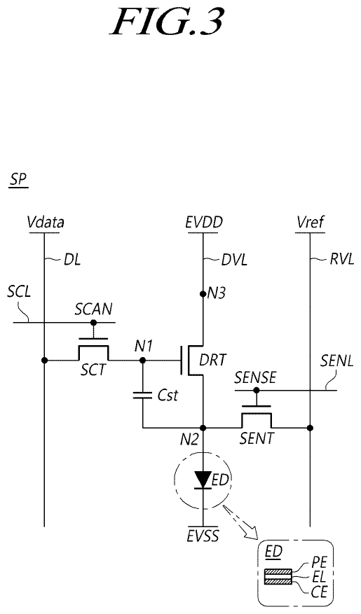

FIG. 2 is an equivalent circuit of a subpixel (SP) of the display device (100) according to aspects of the present disclosure, and FIG. 3 is another equivalent circuit of a subpixel of the display device (100) according to aspects of the present disclosure.

Referring to FIG. 2, each of multiple subpixels (SP) disposed in the display panel (110) of the display device (100) according to aspects of the present disclosure may at least include a light-emitting element (ED), a drive transistor (DRT), a scanning transistor (SCT), and a storage capacitor (Cst), but is not limited thereto. each of the multiple subpixels (SP) may include other elements which are not shown.

Referring to FIG. 2, the light-emitting element (ED) includes a pixel electrode (PE) and a common electrode (CE) and may include a light-emitting layer (EL) positioned between the pixel electrode (PE) and the common electrode (CE). For example, the light-emitting layer (EL) may be formed by inorganic light-emitting material or organic light-emitting material.

The pixel electrode (PE) of the light-emitting element (ED) is an electrode that is disposed for each subpixel (SP), and the common electrode (CE) may be an electrode that is disposed to be common to all the subpixels (SP). Here, the pixel electrode (PE) may be an anode electrode, and the common electrode (CE) may be a cathode electrode. However, aspects of the present disclosure are not limited thereto, the pixel electrode (PE) may be a cathode electrode, and the common electrode (CE) may be an anode electrode.

For example, the light-emitting element (ED) may be an organic light-emitting diode (OLED), an inorganic material-based light-emitting diode (LED), a quantum dot light-emitting element, or the like.

The drive transistor (DRT) is a transistor used for driving a light-emitting element (ED) and may include a first node (N1), a second node (N2), a third node (N3), and the like and may be an n-type transistor or a p-type transistor. Here, when the transistor is an n-type transistor, the turn-on level voltage may be a high level voltage, and the turn-off level voltage may be a low level voltage. When the transistor is a p-type transistor, the turn-on level voltage may be a low level voltage and the turn-off level voltage may be a high level voltage.

The first node (N1) of the drive transistor (DRT) may be a gate node of the drive transistor (DRT) and may be electrically connected to a source node or a drain node of the scanning transistor (SCT). The second node (N2) of the drive transistor (DRT) may be a source node or a drain node of the drive transistor (DRT), may be electrically connected to a source node or a drain node of the sensing transistor (SENT) (see FIG. 3), and may also be electrically connected to the pixel electrode (PE) of the light-emitting element (ED). The third node (N3) of the drive transistor (DRT) may be electrically connected to a drive voltage line (DVL) that supplies a drive voltage (EVDD).

The scanning transistor (SCT) is controlled in accordance with a scanning gate signal (SCAN) that is one type of gate signal and may be connected between the first node (N1) of the drive transistor (DRT) and the data line (DL). In other words, the scanning transistor (SCT) is turned on or turned off in accordance with a scanning signal (SCAN) supplied from a scanning signal line (SCL) that is one type of gate line (GL) and may control connection between the data line (DL) and the first node (N1) of the drive transistor (DRT).

The scanning transistor (SCT) is turned on in accordance with a scanning gate signal (SCAN) having a turn-on level voltage and may transfer a data voltage (Vdata) supplied from the data line (DL) to the first node (N1) of the drive transistor (DRT).

Here, in a case in which the scanning transistor (SCT) is an n-type transistor, the turn-on level voltage of the scanning gate signal (SCAN) may be a high-level voltage. In a case in which the scanning transistor (SCT) is a p-type transistor, the turn-on level voltage of the scanning gate signal (SCAN) may be a low-level voltage.

The storage capacitor (Cst) may be connected between the first node (N1) and the second node (N2) of the drive transistor (DRT). In the storage capacitor (Cst), an electric charge amount corresponding to a voltage difference between both ends is charged, and the storage capacitor (Cst) has a role for maintaining a voltage difference between both the ends (e. g., node N1 and node N2) for a set frame time. In accordance with this, a corresponding subpixel (SP) may emit light for the set frame time.

Referring to FIG. 3, each of multiple subpixels (SP) disposed in the display panel (110) of the display device (100) according to aspects of the present disclosure may further include a sensing transistor (SENT).

The sensing transistor (SENT) is controlled in accordance with a sensing gate signal (SENSE) that is one type of gate signal and may be connected between the second node (N2) of the drive transistor (DRT) and a reference voltage line (RVL). In other words, the sensing transistor (SENT) is turned on or turned off in accordance with a sensing gate signal (SENSE) supplied from a sensing signal line (SENL) that is another type of gate line (GL) and may control connection between the reference voltage line (RVL) and the second node (N2) of the drive transistor (DRT).

The sensing transistor (SENT) is turned on in accordance with a sensing gate signal (SENSE) having a turn-on level voltage and may transfer a reference voltage (Vref) supplied from the reference voltage line (RVL) to the second node (N2) of the drive transistor (DRT).

In addition, the sensing transistor (SENT) is turned on in accordance with a sensing gate signal (SENSE) having a turn-on level voltage and may transfer a voltage of the second node (N2) of the drive transistor (DRT) to the reference voltage line (RVL).

Here, in a case in which the sensing transistor (SENT) is an n-type transistor, the turn-on level voltage of the sensing gate signal (SENSE) may be a high-level voltage. In a case in which the sensing transistor (SENT) is a p-type transistor, the turn-on level voltage of the sensing gate signal (SENSE) may be a low-level voltage.

The function of the sensing transistor (SENT) to transfer the voltage of the second node (N2) of the drive transistor (DRT) to the reference voltage line (RVL) may be used at the time of performing driving for sensing a characteristic value of the subpixel (SP). In such a case, the voltage transferred to the reference voltage line (RVL) may be a voltage used for calculating a characteristic value of the subpixel SP or a voltage in which the characteristic value of the subpixel (SP) is reflected.

Each of the drive transistor (DRT), the scanning transistor (SCT), and the sensing transistor (SENT) may be either an n-type transistor or a p-type transistor. In the present disclosure, for convenience of description, a case in which each of the drive transistor (DRT), the scanning transistor (SCT), and the sensing transistor (SENT) is the n-type will be described as an example.

The storage capacitor (Cst) may be not a parasitic capacitor (for example, Cgs or Cgd) that is an internal capacitor present between the gate node and the source node (or the drain node) of the drive transistor (DRT) but an external capacitor that is intentionally designed outside the drive transistor (DRT).

The scanning signal line (SCL) and the sensing signal line (SENL) may be mutually different gate lines (GL). In such a case, the scanning signal (SCAN) and the sensing signal (SENSE) may be independent gate signals, and an on-off timing of the scanning transistor (SCT) and an on-off timing of the sensing transistor (SENT) disposed inside one subpixel (SP) may be independent from each other. In other words, the on-off timing of the scanning transistor (SCT) and the on-off timing of the sensing transistor (SENT) inside one subpixel (SP) may be the same or be different from each other.

Differently from this, the scanning signal line (SCL) and the sensing signal line (SENL) may be the same gate line (GL). In other words, a gate node of the scanning transistor (SCT) and a gate node of the sensing transistor (SENT) inside one subpixel (SP) may be connected to one gate line (GL). In such a case, the scanning signal (SCAN) and the sensing signal (SENSE) may be the same gate signal, and the on-off timing of the scanning transistor (SCT) and the on-off timing of the sensing transistor (SENT) inside one subpixel (SP) may be the same.

The structures of the subpixel (SP) illustrated in FIGS. 2 and 3 are examples and may be variously changed by further including one or more transistors and further includes one or more capacitors. For example, a number of transistors in the pixel circuit of the present disclosure may be three or more, and a number of storage capacitor may be one or more, for example, the pixel circuit of the present disclosure also may be a 3T1C pixel circuit including three transistors and one storage capacitor, a 3T2C pixel circuit including three transistors and two storage capacitors, a 5T1C pixel circuit including five transistors and one storage capacitor, a 5T2C pixel circuit including five transistors and two storage capacitors, a 7T2C pixel circuit including seven transistors and two storage capacitors, or the like.

In FIGS. 2 and 3, although the subpixel structures have been described by assuming a case in which the display device (100) is a self-emission display device, in a case in which the display device (100) is a liquid crystal display device, each subpixel (SP) may include a transistor, a pixel electrode, common electrode, liquid crystal layer, and the like.

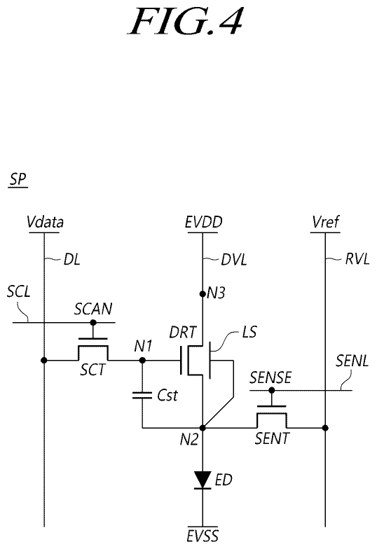

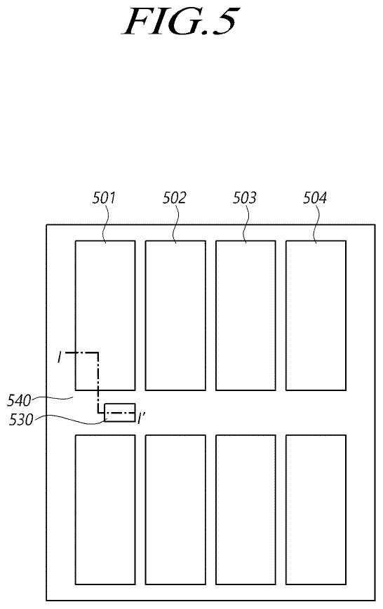

FIG. 4 is a diagram illustrating a light shield (LS) inside a subpixel of a display device (100) according to aspects of the present disclosure.

Referring to FIG. 4, in the subpixel (SP) of the display device (100) according to aspects of the present disclosure, a drive transistor (DRT) may have intrinsic characteristic values such as a threshold voltage, mobility, and the like. When the intrinsic characteristic values of the drive transistor (DRT) change, a current driving capability (a current supply performance) of the drive transistor (DRT) change, and thus light emission characteristics of a corresponding subpixel (SP) may also change.

In accordance with elapse of a drive time of the drive transistor (DRT), element characteristics (for example, a threshold voltage, mobility, and the like) of the drive transistor (DRT) may change. In addition, in a case in which light is emitted to the drive transistor (DRT), particularly, in a case in which light is emitted to a channel region of the drive transistor (DRT), the element characteristics (for example, a threshold voltage, mobility, and the like) of the drive transistor (DRT) may change.

Thus, as illustrated in FIG. 4, to decrease changes in the element characteristics (for example, a threshold voltage change, a mobility change, and the like) of the drive transistor (DRT), a light shield (LS) may be formed near the drive transistor (DRT). For example, the light shield (LS) may be formed under the channel region of the drive transistor (DRT), but the present disclosure is not limited thereto.

The light shield (LS) may be formed in a lower part of the channel region of the drive transistor (DRT) and take the role of a body of the drive transistor (DRT).

While a body effect may occur in the drive transistor (DRT), to reduce an influence of such a body effect, the light shield (LS) taking the role of the body of the drive transistor (DRT) may be electrically connected to the second node (N2) of the drive transistor (DRT). Here, the second node (N2) of the drive transistor (DRT) may be the source node of the drive transistor (DRT).

On the other hand, the light shield (LS) may be disposed not only in a lower part of the channel region of the drive transistor (DRT) but also in a lower part of channel regions of other transistors (for example, SCT and SENT).

Hereinafter, a thin film transistor TFT structure enabling thin film transistors disposed in the display panel (110) to have high performance, high stability, and high reliability will be described.

For example, in the process of forming a thin film transistor, in a case in which a gate insulating film or another electrode formed on a semiconductor layer at a position close to a channel region of the semiconductor layer is etched, there is a risk of the semiconductor layer missing or being damaged in the etching process. Aspects of the present disclosure may provide a thin film transistor structure for reducing the risk described above in the process.

Here, thin film transistors having the thin film transistor structure according to aspects of the present disclosure may be some or all of the thin film transistors disposed in the display panel (110). For example, thin film transistors having the thin film transistor structure according to aspects of the present disclosure may include all or some of the transistors disposed inside each subpixel (SP). As another example, thin film transistors having the thin film transistor structure according to aspects of the present disclosure may include all or some of transistors disposed inside a gate driving circuit (130) of a GIP type.

FIG. 5 is a plan view illustrating an example of subpixels disposed in an X area illustrated in FIG. 1. For example, FIG. 5 is a diagram illustrating a plane of subpixels disposed in the display region (DA) by enlarging an X area that is one area of the display region (DA) of the display device (100) illustrated in FIG. 1.

Referring to FIG. 5, multiple subpixels (501, 502, 503, 504) are disposed in the display region (DA), and a bank layer (540) is disposed between subpixels to define each of subpixels. In other words, multiple subpixels (501, 502, 503, 504) may be partitioned by the bank layer (540).

As the multiple subpixels (501, 502, 503, 504), although a red subpixel (501), a black subpixel (502), a green subpixel (503), and a blue subpixel (504) may be disposed in order with a constant gap interposed therebetween to form one pixel, the configuration is not limited thereto, for example, the gaps of two subpixels adjacent to each other among the red subpixel (501), the black subpixel (502), the green subpixel (503), and the blue subpixel (504) may be same or different. In addition, multiple subpixels (501, 502, 503, 504) may be of other color.

Referring to FIG. 5, a light receiving part (530) may be disposed between subpixels. The light receiving part (530) may be disposed such that it does not overlap with the bank layer (540). In other words, in an area in which the light receiving part (530) is disposed, the bank layer (540) may be removed.

Although the structure in which the light receiving part (530) is disposed between subpixels is illustrated in FIG. 5, the structure is not limited thereto. For example, the light receiving part may be disposed in a subpixel.

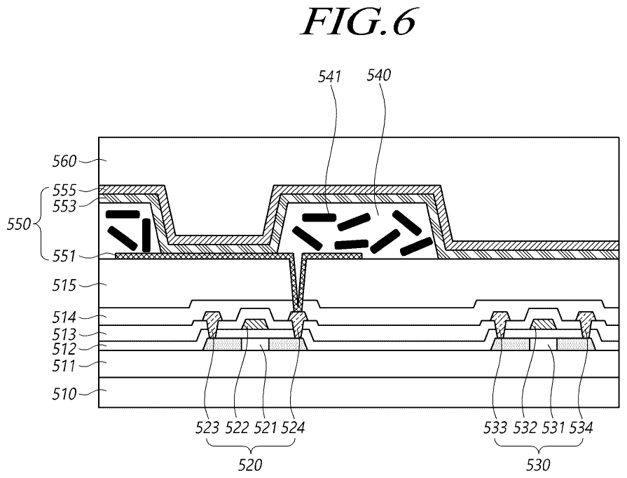

FIG. 6 is a cross-sectional view illustrating a cross-section of a subpixel cut along line I-I′ illustrated in FIG. 5.

Referring to FIG. 6, a substrate (510) and a multi-buffer layer (511) may be included, and a driver transistor (520) may be disposed on the multi-buffer layer (511).

In the drive transistor (520), an active layer (521) disposed on a multi-buffer layer (511), a gate electrode (522) and a gate insulating layer (512) for insulation on the active layer (521), and a first insulation layer (513) on a gate electrode (522) may be disposed, and source and drain electrodes (523, 524) that are formed on the gate electrode (522) and the first insulation layer (513) and are in contact with the active layer (521) may be provided. Here, the active layer (521) may be formed using at least one of an amorphous semiconductor material, a polycrystalline semiconductor material, and an oxide semiconductor material. In this example, the drive transistor (520) is formed in top gate type, but the aspect of present disclosure is not limited thereto, the drive transistor (520) is formed in bottom gate type or dual gate type.

The multi-buffer layer (511) may prevent or delay moisture or oxygen that has penetrated the substrate (510) from spreading and may be formed by alternately stacking a silicon nitride (SiNx) and a silicon oxide (SiOx) at least once. For example, the multi-buffer layer (511) may have a structure of silicon nitride (SiNx), silicon oxide (SiOx) and silicon nitride (SiNx) stacked sequentially, alternatively, the multi-buffer layer (511) may have a structure of silicon oxide (SiOx), silicon nitride (SiNx) and silicon oxide (SiOx) stacked sequentially, but the aspects of the present disclosure are not limited thereto.

The active layer (521) of the drive transistor (520) may formed using a polycrystalline semiconductor layer, and the active layer (521) may include a channel region and a source region and a drain region both of which are disposed at both sides of the channel region.

A polycrystalline semiconductor material has mobility higher than an amorphous semiconductor material and an oxide semiconductor material and has low energy power consumption and superior reliability. In accordance such advantages, a polycrystalline semiconductor layer may be used in the drive transistor (520).

In particular, since the polycrystalline semiconductor material has a faster movement speed of carriers such as electrons and holes than that of the oxide semiconductor material, the polycrystalline semiconductor material is suitable for driving TFTs requiring fast driving. As a result, driving TFTs use a polycrystalline semiconductor material.

The oxide TFT may have an excellent effect of preventing a leakage current and relatively inexpensive manufacturing cost compared to polycrystalline TFTs. Therefore, according to the aspect of the present disclosure, at least one switching TFT may be also manufactured using the oxide semiconductor material.

The oxide semiconductors may be made of a metal oxide such as zinc (Zn), indium (In), gallium (Ga), tin (Sn), and titanium (Ti) or a combination of a metal such as zinc (Zn), indium (In), gallium (Ga), tin (Sn), and titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The gate electrode (522) may be disposed on the gate insulating layer (512) and may be disposed to overlap with the active layer (521).

The gate electrode (522) may be a single layer or a multiple layer formed using any one of molybdenum (Mo), aluminum (Al), chrome (Cr), gold (Au), titanium (Ti), nickel (Ni), neodymium (Nd), and copper (Cu) or an alloy thereof but is not limited thereto.

Each of the source and drain electrodes (523, 524) may be a single layer or a multiple layer formed using any one of molybdenum (Mo), aluminum (Al), chrome (Cr), gold (Au), titanium (Ti), nickel (Ni), neodymium (Nd), and copper (Cu) or an alloy thereof but is not limited thereto.

In addition, the gate electrode (522) and the source and drain electrodes (523, 524) may be formed to include the same material and have the same structure, alternatively, the gate electrode (522) and the source and drain electrodes (523, 524) may be formed to include different materials and have different structures, but the aspects of the present disclosure are not limited thereto.

A second insulation layer (514) and a planarization layer (515) may be disposed on the first insulation layer (513) and the source and drain electrodes (523, 524).

The second insulating layer (514) may be formed using a silicon nitride (SiNx) or a silicon oxide (SiOx), and the planarization layer (515) may be formed using photo acryl or an organic material.

A through hole may be formed in the second insulation layer (514) and the planarization layer (515), and a first electrode (551) that is electrically connected to the drain electrode (524) exposed through the through hole may be disposed.

The light-emitting element (550) may be formed using a first electrode (551), an organic layer formed on the first electrode (551), a second electrode (555) formed on the organic layer, and the like. The organic layer includes one or more light-emitting layers (553) and may additionally include a hole injection layer, a hole transport layer, an electron transport layer, an electron injection layer, and a charge generation layer other than the light-emitting layers, but the aspects of the present disclosure are not limited thereto.

In such a case, when voltages are applied to the first electrode (551) and the second electrode (555), holes and electrons move to the light-emitting layer (553) respectively through the hole transport layer and the electron transport layer and are combined together in the light-emitting layer (553) to emit light.

A bank layer (540) may be disposed on the first electrode (551). The bank layer (540) may be disposed to cover an outskirt part of the first electrode (551), and an opening part at the center of the first electrode (551). The bank layer (540) may be disposed in an outskirt part of the first electrode (551) and have a plane of a matrix form.

The bank layer (540) may include nano rods (541). The nano rods (541) included in the bank layer (540) may absorb light of a visible light region and emit light of a near-infrared region.

An encapsulation part (560) may be disposed on the second electrode (555). A capping layer (not shown) may be further disposed between the second electrode (555) and the encapsulation part (560). The capping layer (not shown) may protect organic layers and the electrode disposed in a lower part, thereby increasing light extraction efficiency, and color correction.

The encapsulation part (560) prevents or minimizes penetration of external moisture and oxygen into the light-emitting element (550) positioned inside the encapsulation part (560). For this, the encapsulation part (560) may include encapsulation layers of first and second inorganic layers or an organic layer, and the like.

The first inorganic layer is formed on the light-emitting element (550), and the first inorganic layer may be formed of an inorganic insulation material that may be deposited at low temperature such as silicon nitride (SiNx), silicon oxide (SiOx), silicon oxynitride (SiON) and aluminum oxide (Al₂O₃). In accordance with this, the first inorganic layer is deposited in a low-temperature environment, and thus damage of the light-emitting layer (553) that is weak to a high-temperature environment may be minimized in a first inorganic layer depositing process.

The organic layer has a buffering role for alleviating a stress between layers according to bending of an organic light-emitting display device and strengthens planarization performance. In addition, the organic layer covers foreign materials (particles) that may be inserted while the first inorganic layer is formed, and, in accordance with this, the second inorganic layer is evenly formed on the first inorganic layer and the organic layer. Thus, an encapsulation function of the encapsulation part may be further improved.

The organic layer is formed of an organic insulation material such as an acrylic resin, an epoxy resin, polyimide, polyethylene, or silicon oxycarbon (SiOC). The organic layer may be formed with a uniform thickness inside a display region or may be formed such that a thickness thereof decreases from the center of the display region toward an edge thereof.

The second inorganic layer is formed to cover an upper face and a side face of each of the organic layer and the first inorganic layer on which the organic layer is formed. In accordance with this, the second inorganic layer may minimize or block penetration of external moisture or oxygen into the first inorganic layer and the organic layer. Such a second inorganic layer is formed using an inorganic insulation material such as a silicon nitride (SiNx), a silicon oxide (SiOx), silicon oxynitride (SiON), and an aluminum oxide (Al₂O₃).

The light receiving part (530) may be disposed to be adjacent to the bank layer (540). The light receiving part (530) may be disposed between subpixels, and the light receiving part (530) and the bank layer (540) may be disposed not to overlap with each other. For example, by removing the bank layer (540) disposed in an upper part of an area in which the light receiving part (530) is disposed, the light receiving part (530) and the bank layer (540) may be disposed not to overlap with each other.

The light receiving part (530) may be disposed in a subpixel. For example, the light receiving part may be disposed by removing the light-emitting element in opening parts of some subpixels.

The light receiving part (530) may be disposed in the same plane as that of the drive transistor 520 used for light emission of the light-emitting element (550), be manufactured using the same configuration and the same process, and not require an additional process for manufacturing the light receiving part (530).

The light receiving part (530) may be a near-infrared ray receiving part receiving light of a near-infrared wavelength. The light receiving part (530) may include a light absorbing layer (531) receiving light of a near-infrared wavelength and transmissive electrodes (533, 534) and a reflective electrode (532) on an upper part of the light absorbing layer (531).

The reflective electrode (532) prevents incident light from being transmitted so that the incident light is not lost. The reflective electrode (532) may be formed using the same material as that of the gate electrode (522) and the first electrode (551) described above. The transmissive electrodes (533, 534) may be formed as transmissive electrodes for maximally absorbing a near-infrared ray and be formed using ITO, IZO, AITO, carbon nanotubes, griffin, or silver nano particles.

The light receiving part (530) may be formed using a material that is appropriate for receiving light of a near-infrared wavelength and, more specifically, may be formed of one of metal phthalocyanine, metal bisdithiolene, and squaraine.

Hereinafter, the bank layer (540) and the nano rods (541) included in the bank layer (540) will be described in detail.

A display device according to an aspect of the present disclosure may include nano rods (541) in the bank layer (540). The bank layer (540) may include the nano rods (541) absorbing light of a visible light region and emitting light of a near-infrared region.

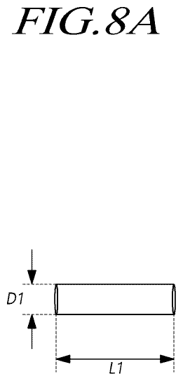

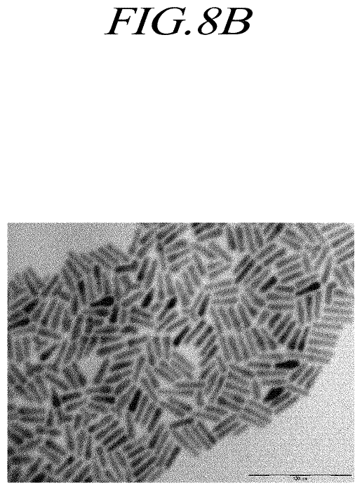

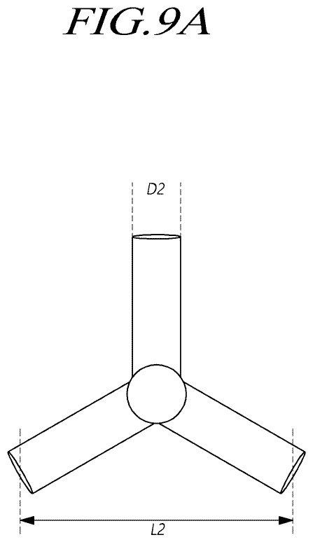

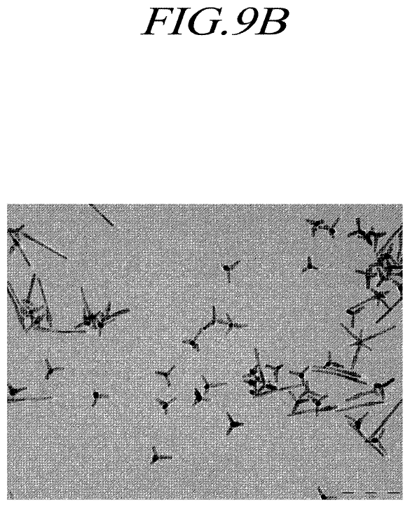

FIG. 8A is a schematic diagram illustrating a shape of a nano rod, and FIG. 8B is a photograph illustrating nano rods included in a bank layer. FIG. 9A is a schematic diagram showing another shape of a nano rod, and FIG. 9B is a photograph illustrating nano rods of another shape included in a bank layer.

Referring to FIG. 8A, the nano rod (541) may include a long axis and a short axis. The aspect ratio of the nano rod (541) may be higher than 1. For example, the aspect ratio between the long axis and the short axis of the nano rod (541) may be two or higher.

In a case in which the aspect ratio of the nano rod (541) is lower than 2, in other words, in a case in which the nano rod has a dot shape, absorbance for visible light is low, and there is a problem in that it is difficult to use the nano rod as a black material of the bank layer.

For example, a length (D1) of the short axis of the nano rod (541) may be 1 nm to 10 nm, and a length (L1) of the long axis thereof may be 2 nm to 1000 nm, or the length (L1) of the long axis may be 2 nm to 50 nm, or 2 nm to 100 nm. Alternatively, a length (D1) of the short axis of the nano rod (541) may be 2 nm to 20 nm, and a length (L1) of the long axis thereof may be 4 nm to 1000 nm, or the length (L1) of the long axis may be 4 nm to 100 nm, or 4 nm to 200 nm, but is not limited thereto.

Referring to FIG. 9A, one end of the nano rod (541) may branch and have at least two branches. For example, one end of the nano rod (541) may branch and may be in a form having two or three branches, alternatively, one end of the nano rod (541) may branch and may be in a form having at least four branches.

In a case in which the nano rod (541) has two or more branches, a short axis (D2) of the nano rod represents a short axis of one branch, and a long axis (L2) of the nano rod represents an axis joining both ends that are the farthest away from the branches that have branched.

Also in a case in which one end of the nano rod (541) branches and has at least two branches, the aspect ratio between the length (L2) of the long axis and the length (D2) of the short axis may be two or more.

For example, the length (D2) of the short axis (D2) of the nano rod (541) may be 1 nm to 10 nm, the length (L2) of the long axis may be 2 nm to 1000 nm, or the length (L2) of the long axis may be 2 nm to 50 nm or 2 nm to 100 nm. Alternatively, the length (D2) of the short axis (D2) of the nano rod (541) may be 2 nm to 20 nm, the length (L2) of the long axis may be 4 nm to 1000 nm, or the length (L2) of the long axis may be 4 nm to 100 nm or 4 nm to 200 nm but is not limited thereto.

The nano rod (541) may include a nano semiconductor compound of IV-VI groups, III-V groups, and II-VI groups. For example, the nano rod (541) may include one of PbSe, PbS, PbScS, InAsP, InP, InAs, HgS, HgSe, and HgSeS.

The nano rod (541) is included in the bank layer (540), and visible light incident in the bank layer (540) is absorbed by the nano rod (541), and a near-infrared ray is emitted. The bank layer (540) may be composed of a photo-acryl based material based on an organic material.

The bank layer (540) may contain 1 wt % to 5 wt % of the nano rod (541) or may contain 1 wt % to 4 wt % of the nano rod (541). When the nano rod (541) less than 1 wt % is contained, the efficiency of conversion of visible light into a near-infrared ray is low, and, in a case in which the nano rod (5541) exceeding 5 wt % is contained, there may be a problem in that the nano rod (541) and the bank layer (540) are away from each other.

In addition, the bank layer (540) may contain a solid content of less than a maximum 20 wt %, and, in such a case, the nano rod may be contained with a maximum 25 wt % or within 20 wt % in the whole solid content.

A thickness of the bank layer (540) containing the nano rod (541) may be 1 μm to 10 μm, or may be 3 μm to 7 μm. When the range of the bank layer (540) described above is satisfied, a black characteristic may be implemented by raising the absorbance for visible light.

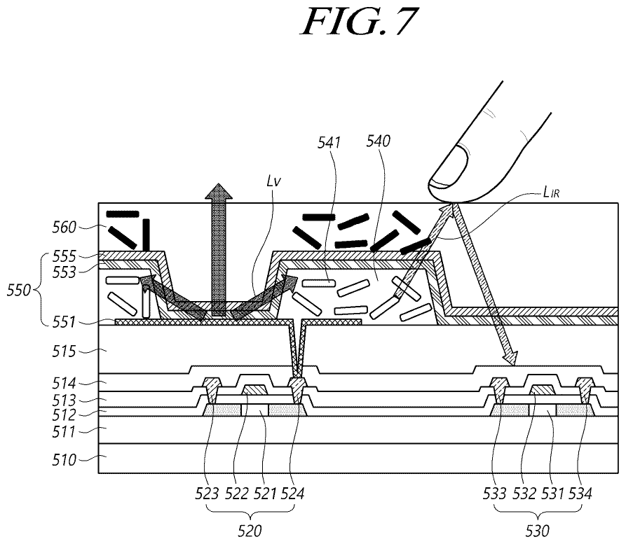

FIG. 7 is a diagram illustrating a process in which, when a touch on a surface of a display device using a finger, a near-infrared ray is received by a light receiving part, and the touch is detected in the structure illustrated in FIG. 6.

Referring to FIG. 7, when a finger is put on the display device according to aspects of the present disclosure, a near-infrared ray emitted by the light-emitting element (550) is emitted to the finger, and a near-infrared ray reflected or scattered by the finger may be received and detected by the light receiving part (530).

In such a case, light (LV) of a visible light region out of light emitted by the light-emitting clement (550) is incident in the bank layer (540) and may be converted into a near-infrared ray (LIR) according to the nano rod (541) disposed inside the bank layer (540). Thus, the emission intensity of a near-infrared ray (LV) emitted by a finger is improved, and a phenomenon in which a near-infrared ray that is reflected or scattered by the finger and is incident in the light receiving part (530) is not received may be minimized.

In the light receiving part (530), the bank layer (540) may be removed for smooth reception of the near-infrared ray. By removing the bank layer (540) in an upper part of an area in which the light receiving part (530) is disposed, a phenomenon in which a near-infrared ray is refracted or scattered in accordance with an index of refraction of the bank layer (540) and is not received by the light receiving part (530) may be minimized.

When a user touches the display device, a near-infrared ray generated by the most adjacent bank layer (540) is reflected and progresses to the inside of the display device, and a part thereof may be incident in the light receiving part (530). The incident near-infrared ray reaches the light absorbing layer (531) of the light receiving part (530), and a photoelectric effect may occur in the light absorbing layer (531) in accordance with a near-infrared ray absorbed by the light absorbing layer (531). By detecting a flow of a current in the light absorbing layer (531) through such a photoelectric effect, it may be detected that a nearby area of the light absorbing layer (531) has been touched.

In the description presented above, although only a touch of a finger has been illustrated, it may be also applied to a fingerprint, an iris, a retina, a face, and the like. Particularly, in the case of a near-infrared ray, the wavelength is larger than that of visible light, and scattering or reflection is smaller than that of visible light, and depth information of images for the images of a fingerprint, an iris, a retina, a face, and the like are acquired, which may be advantageous.

As a near-infrared ray emitted in the bank layer reaches an object without being scattered on the surface, the near-infrared ray may be advantageously detected in the light receiving part. In such a case, the lower roughness of the surface of the bank layer, the more advantageous it is.

Table 1 represented below illustrates results of measurement of surface roughness (Rq) according to a material included in the bank layer acquired using an atomic force microscope (AFM).

Comparative Example 1 is a bank layer formed by applying a photo acryl-based resin, Comparative Example 2 is a bank layer formed by applying a resin containing a black dye in a solid content, Comparative Example 3 is a bank layer formed by applying a resin in which 30 wt % of nano dots is contained in a solid content, Aspect 1 is a bank layer formed by applying a resin in which 15 wt % of nano rods is included in a solid content, and Aspect 2 is a bank layer formed by applying a resin in which 15 wt % of nano rods of a tetrapod form is included in a solid content.

TABLE 1

| | Comparative | Comparative | Comparative | Aspect | Aspect |
|---|---|---|---|---|---|
| | Example 1 | Example 2 | Example 3 | 1 | 2 |
| Rq(nm) | 0.31 | 10.8 | 2.85 | 2.51 | 2.62 |

In Comparative Example 1, although the surface roughness is the lowest, only a resin is included, and visible light cannot be absorbed. In Comparative Example 2, although visible light may be absorbed, the surface roughness is high, and scattering of light may be generated on the surface. In Comparative Example 3, 30 wt % of nano dots, which is a considerably large amount, needs to be contained in a solid content.

On the other hand, in Aspects 1 and 2, it may be checked that, although a small amount of nano rods is contained in the solid content, the roughness is low, and thus a near-infrared ray is not scattered on the surface of the bank layer and may reach an object.

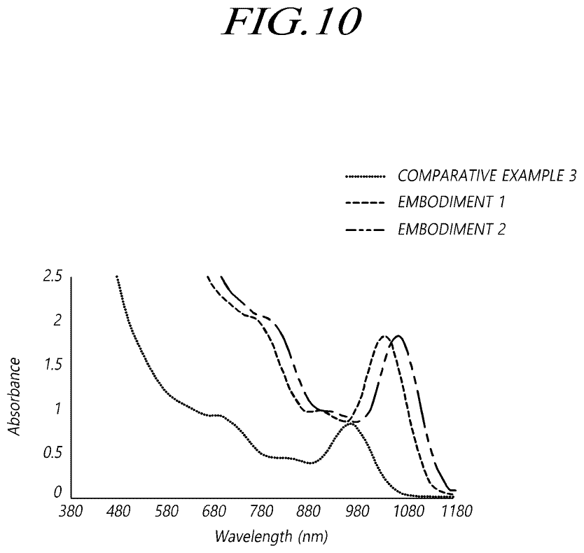

FIGS. 10 to 12 are graphs illustrating optical characteristics of display devices according to aspects of the present disclosure.

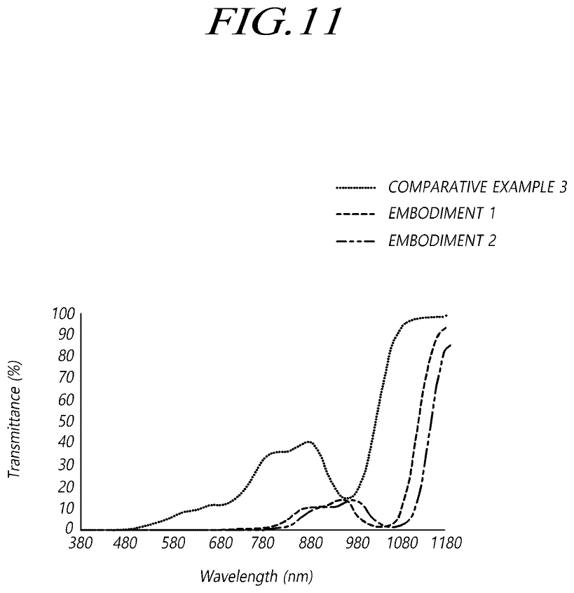

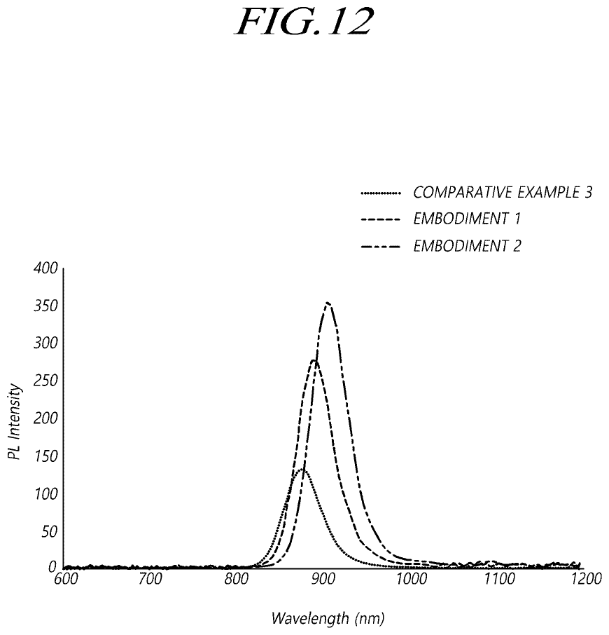

For example, FIG. 10 are graphs illustrating absorbance according to wavelengths of display devices according to Comparative Example 3 and Aspects 1 and 2, FIG. 11 are graphs illustrating transmittance according to wavelengths of display devices according to Comparative Example 3 and Aspects 1 and 2, and FIG. 12 are graphs illustrating emission intensities (PL intensity) according to wavelengths of the display devices according to Comparative Example 3 and Aspects 1 and 2.

Referring to FIGS. 10 and 11, it may be checked that, compared to Comparative Example 3, Aspects 1 and 2 represent high absorbance and low transmittance in a band of about 380 nm to 700 nm that is a wavelength band of visible light. Thus, in the display device according to aspects of the present disclosure, by including nano rods in the bank layer, the whole wavelength band of visible light is absorbed, black characteristics are implemented, and a black visual sense may be improved.

Referring to FIG. 12, it may be checked that, compared to Comparative Example 3, Aspects 1 and 2 represent a high emission intensity in the band of 780 nm to 1000 nm that is a near-infrared ray wavelength band. Thus, in the display device according to aspects of the present disclosure, by including nano rods, the bank layer absorbs a light source of a visible light region that is emitted by a light-emitting element and may implement characteristics for emitting a near-infrared ray and may be applied to an infrared sensor.

The aspects of the present disclosure described above will be briefly described as below.

Aspects of the present disclosure may provide a display device including: a substrate (510) including a light emission region and a non-light emission region; a light-emitting element (550) disposed on the substrate and including a first electrode (551), a light-emitting layer (553), and a second electrode (555); and a bank layer (540) defining an opening part of the light emission region and containing a nano rod (541).

An aspect ratio between a long axis and a short axis of the nano rod (541) may be two or more.

A length (D1, D2) of the short axis of the nano rod (541) may be 1 nm to 10 nm, and a length (L1, L2) of the long axis of the nano rod (541) may be 2 nm to 1000 nm.

One end of the nano rod (541) branches and has at least two branches.

The nano rod may include nano semiconductor compound.

The nano semiconductor compound may include one of PbSe, PbS, PbSeS, InAsP, InP, InAs, HgS, HgSe, and HgSeS.

The nano rod (541) may absorb light of a visible light region and emit light of a near-infrared region.

The near-infrared ray may be light having a wavelength of 780 nm to 1000 nm.

The bank layer (540) may contain 1 wt % to 5 wt % of the nano rod (541).

A thickness of the bank layer (540) may be 1 μm to 10 μm.

A light receiving part (530) disposed adjacent to the bank layer (540) may be further included.

The light receiving part may include a light absorbing layer receiving near-infrared ray and transmissive electrodes and a reflective electrode on an upper part of the light absorbing layer

The display device further comprise a drive transistor, the light absorbing layer is disposed in a same plane as that of an active layer of the drive transistor, the transmissive electrodes are disposed in a same plane as that of source and drain electrodes of the drive transistor, and the reflective electrode is disposed in a same plane as that of a gate electrode of the drive transistor.

The light receiving part (530) and the bank layer (540) may be disposed not to overlap with each other.

Aspects of the present disclosure may provide a display device including: a substrate (510) including a plurality of subpixels; a bank layer (540) disposed on the substrate and defining the plurality of subpixels; and a light receiving part (530) disposed adjacent to the bank layer and receiving light of a near-infrared region, in which the bank layer (540) contains a nano rod (541) absorbing light of a visible light region and emitting light of the near-infrared region.

The light receiving part may include a light absorbing layer receiving near-infrared ray and transmissive electrodes and a reflective electrode on an upper part of the light absorbing layer.

The display device may further comprise a drive transistor, the light absorbing layer is disposed in a same plane as that of an active layer of the drive transistor, the transmissive electrodes are disposed in a same plane as that of source and drain electrodes of the drive transistor, and the reflective electrode is disposed in a same plane as that of a gate electrode of the drive transistor.

An aspect ratio between a long axis and a short axis of the nano rod (541) may be two or more.

A length (D1, D2) of the short axis of the nano rod (541) may be 1 nm to 10 nm, and a length (L1, L2) of the long axis may be 2 nm to 1000 nm.

One end of the nano rod (541) branches and has at least two branches.

The nano rod may include nano semiconductor compound.

The nano semiconductor compound may include one of PbSe, PbS, PbSeS, InAsP, InP, InAs, HgS, HgSe, and HgSeS.

The bank layer (540) may contain 1 wt % to 5 wt % of the nano rod (541).

The light receiving part and the bank layer may be disposed not to overlap with each other.

The light receiving part may be disposed in or between the at least one subpixels.

A display device according to aspects of the present disclosure may implement black characteristics by absorbing the whole wavelength band of visible light and improve a black visual sense by introducing nano rods into a bank layer.

A display device according to aspects of the present disclosure, by introducing nano rods into a bank layer, may implement near-infrared light emission characteristics by absorbing a light source of a visible light region emitted from a light-emitting element.

A display device according to aspects of the present disclosure, by introducing nano rods into a bank layer, may improve the process and dispersion stability of materials by lowering a solid content.

A display device according to aspects of the present disclosure, by introducing nano rods into a bank layer, may enable process optimization.

The above description has been presented to enable any person skilled in the art to make and use the technical idea of the present disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the present disclosure. The above description and the accompanying drawings provide an example of the technical idea of the present disclosure for illustrative purposes only. That is, the disclosed aspects are intended to illustrate the scope of the technical idea of the present disclosure.

It will be apparent to those skilled in the art that various modifications and variations can be made in the display device of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A display device comprising:
a substrate including a light emission region and a non-light emission region; and
a bank layer defining an opening part of the light emission region and containing a nano rod.

2. The display device according to claim 1, wherein an aspect ratio between a long axis and a short axis of the nano rod is two or more.

3. The display device according to claim 2, wherein a length of the short axis of the nano rod is 1 nm to 10 nm, and a length of the long axis of the nano rod is 2 nm to 1000 nm.

4. The display device according to claim 1, wherein one end of the nano rod branches and has at least two branches.

5. The display device according to claim 1, wherein the nano rod includes a nano semiconductor compound.

6. The display device according to claim 5, wherein the nano semiconductor compound includes one of PbSe, PbS, PbSeS, InAsP, InP, InAs, HgS, HgSe, and HgSeS.

7. The display device according to claim 1, wherein the nano rod absorbs light of a visible light region and emits near-infrared ray of a near-infrared region.

8. The display device according to claim 7, wherein the near-infrared ray has a wavelength of 780 nm to 1000 nm.

9. The display device according to claim 1, wherein the bank layer contains 1 wt % to 5 wt % of the nano rod.

10. The display device according to claim 9, wherein a thickness of the bank layer is 1 μm to 10 μm.

11. The display device according to claim 1, further comprising a light receiving part disposed adjacent to the bank layer.

12. The display device according to claim 11, wherein the light receiving part includes a light absorbing layer receiving near-infrared ray and transmissive electrodes and a reflective electrode on an upper part of the light absorbing layer.

13. The display device according to claim 12, further comprising a drive transistor,
wherein the light absorbing layer is disposed in a same plane as that of an active layer of the drive transistor,
wherein the transmissive electrodes are disposed in a same plane as that of source and drain electrodes of the drive transistor, and
wherein the reflective electrode is disposed in a same plane as that of a gate electrode of the drive transistor.

14. The display device according to claim 11, wherein the light receiving part and the bank layer are disposed not to overlap with each other.

15. A display device comprising:
a substrate including at least one subpixel;
a bank layer disposed on the substrate and defining the subpixel; and
a light receiving part disposed adjacent to the bank layer and receiving light of a near-infrared region,
wherein the bank layer contains a nano rod absorbing light of a visible light region and emitting light of the near-infrared region.

16. The display device according to claim 15, wherein the light receiving part includes a light absorbing layer receiving the light of a near-infrared region and transmissive electrodes and a reflective electrode on an upper part of the light absorbing layer.

17. The display device according to claim 16, further comprising a drive transistor,
wherein the light absorbing layer is disposed in a same plane as that of an active layer of the drive transistor,
wherein the transmissive electrodes are disposed in a same plane as that of source and drain electrodes of the drive transistor, and
wherein the reflective electrode is disposed in a same plane as that of a gate electrode of the drive transistor.

18. The display device according to claim 15, wherein an aspect ratio between a long axis and a short axis of the nano rod is two or more.

19. The display device according to claim 18, wherein a length of the short axis of the nano rod is 1 nm to 10 nm, and a length of the long axis is 2 nm to 1000 nm.

20. The display device according to claim 15, wherein one end of the nano rod branches and has at least two branches.

21. The display device according to claim 15, wherein the nano rod includes nano semiconductor compound.

22. The display device according to claim 21, wherein the nano semiconductor compound includes one of PbSe, PbS, PbSeS, InAsP, InP, InAs, HgS, HgSe, and HgSeS.

23. The display device according to claim 15, wherein the bank layer contains 1 wt % to 5 wt % of the nano rod.

24. The display device according to claim 15, wherein the light receiving part and the bank layer are disposed not to overlap with each other.

25. The display device according to claim 15, wherein the light receiving part is disposed in or between the at least one subpixels.
